(19) United States
(12) Patent Application Publication
(10) Pub. No.: US 2025/0029960 A1
(43) Pub. Date: Jan. 23, 2025

(54) LIGHT BOARD, DISPLAY DEVICE, AND METHOD OF ASSEMBLING LIGHT BOARD

(71) Applicant: HKC CORPORATION LIMITED, Shenzhen (CN)

(72) Inventors: HONGSONG WANG, Shenzhen (CN); Junfeng XIE, Shenzhen (CN)

(21) Appl. No.: 18/670,737

(22) Filed: May 22, 2024

(30) Foreign Application Priority Data
Jul. 17, 2023 (CN) 202310872969.7

(51) Int. Cl. H01L 25/075

(52) U.S. Cl. CPC H01L 25/0753

(57) ABSTRACT

A light board, a display device, and a method of assembling the light board are disclosed. The light board includes a bottom plate, a main capacitor plate, an assembling structure, and multiple light-emitting chips. There are disposed multiple partition plates on the bottom plate, and the multiple partition plates divide the bottom plate into multiple sections. Multiple light-emitting chips are respectively arranged in the multiple sections. A first electrostatic coating is disposed on a top surface of each light-emitting chip. The main capacitor plate is arranged opposite to the bottom plate, and the light-emitting chips are disposed between the bottom plate and the main capacitor plate. The assembling structure is disposed on the bottom plate, and is connected to the main capacitor plate. The assembling structure is operative to drive the main capacitor plate to reciprocate in a direction toward or away from the bottom plate.

### CROSS-REFERENCE TO RELATED APPLICATIONS

This application claims the priority and benefit of Chinese patent application number 2023108729697, titled “Light Board, Display Device, and Method of Assembling Light Board” and filed Jul. 17, 2023 with China National Intellectual Property Administration, the entire contents of which are incorporated herein by reference.

### TECHNICAL FIELD

This application relates to the technical field of light boards, and more particularly relates to a light board, a display device, and a method of assembling the light board.

### BACKGROUND

The description provided in this section is intended for the mere purpose of providing background information related to the present application but doesn't necessarily constitute prior art.

With the innovation and development of LED (light-emitting diode) technology, Micro-LED (Micro Light-emitting Diode Display) display technology has become a new generation of display technology. It consists in miniaturizing and matrixing the LED structures, so that the size of a single LED chip is reduced to tens of microns or even a few microns, and each LED pixel is addressed and individually driven to emit light. Since Micro-LED chip displays have the advantages of high resolution, high brightness, long life span, wide operating temperature range, strong anti-interference ability, fast response speed, and low power consumption, Micro-LED has important application values in the fields of high-resolution display, helmet display, augmented reality, high-speed visible light communication, micro-projector, optogenetics, and wearable electronics.

A full-color gamut Micro-LED display is assembled from Micro-LED chips in three primary colors of red, green, and blue (RGB) on a substrate in a certain arrangement. In a possible RGB arrangement, each group uses three chips of red, green, and blue, which are evenly spaced in a horizontal plane to realize an RGB effect. The size of a single group is relatively large, and it is also difficult to assemble in that three chips of red, green, and blue need to be arranged in sequence. As such, the number of chips transferred in a mass transfer process is relatively large, which leads to relatively high requirements on the mass transfer process of the Micro-LEDs and a low efficiency and poor accuracy in mass transfer.

### SUMMARY

In view of the above, it is therefore a purpose of this application to provide a light board, a display device, and a method of assembling the light board, whereby by arranging a main capacitor plate and a light-emitting chip, the accuracy required when the light-emitting chips are transferred to the light board in large quantities is reduced, and the requirements for the Micro-LED mass transfer process are reduced.

This application discloses a light board, which is applied to a display device. The light board includes a bottom plate, a main capacitor plate, an assembling structure, and a plurality of light-emitting chips. Multiple partition plates are disposed on the bottom plate. The plurality of partition plates divide the bottom plate into a plurality of sections. A plurality of light-emitting chips are respectively arranged in the plurality of sections. A first electrostatic coating is disposed on a top surface of each light-emitting chip. The main capacitor plate is arranged opposite to the bottom plate. The light-emitting chip is located between the bottom plate and the main capacitor plate. The assembling structure is arranged on the bottom plate. The assembling structure is connected to the main capacitor plate. The assembling structure drives the main capacitor plate to reciprocate in a direction toward or away from the bottom plate. When the main capacitor plate is energized, the light-emitting chip moves toward the main capacitor plate under the action of the first electrostatic coating. The assembling structure drives the main capacitor plate to move in a direction away from the bottom plate to drive the light-emitting chip, so that the light-emitting chip rotates until the top surface of the light-emitting chip is attached with the main capacitor plate. The light emitted by the light-emitting chip can pass through the main capacitor plate and emit out of the main capacitor plate for display.

In some embodiments, the assembling structure includes a driving piece, a transmission assembly, and a connecting rod. The driving piece is connected to the transmission assembly. The transmission assembly is connected to the connecting rod. The connecting rod is connected to the main capacitor plate. When the driving piece is operating, the driving piece drives the transmission assembly to move. The transmission assembly drives the connecting rod to move back and forth in a direction toward or away from the bottom plate, thereby driving the main capacitor plate to move.

In some embodiments, the driving piece includes a motor. The transmission assembly includes a first transmission gear, a second transmission gear, and a crank rod. The output shaft of the motor is connected to the first transmission gear. The first transmission gear meshes with the second transmission gear. The second transmission gear is connected to the crank rod. The crank rod is connected to the connecting rod.

In some embodiments, a suction piece is disposed on the connecting rod. The suction piece is connected to the main capacitor plate to hold the main capacitor plate onto the connecting rod.

In some embodiments, a groove is also defined in the bottom plate. The groove is disposed corresponding to each partition plate. The elastic piece is arranged in the groove. A support plate is disposed on one end of the partition plate adjacent to the groove. One end of the elastic piece abuts on the bottom of the groove, and the other end abuts on the support plate. When the main capacitor plate moves toward the bottom plate, the main capacitor plate contacts the partition plate to drive the partition plate to move toward the bottom of the groove.

In some embodiments, a sub-capacitor plate is also disposed on the partition plate. The sub-capacitor plate is disposed on a side of the partition plate facing the section. The opposite sub-capacitor plates in each section have opposite polarities. Adjacent sub-capacitor plates have the same polarity.

In some embodiments, the height of the partition plate disposed at the outermost side of the bottom plate is greater than the height of the partition plates disposed at other positions of the bottom plate. The depth of the groove disposed corresponding to the outermost partition plate is greater than the depth of the groove disposed corresponding to the partition plates at other positions.

In some embodiments, a power supply board is also disposed on the bottom plate. The power supply board includes connecting holes. Pins are disposed on the bottom surface of the light-emitting chip. When the light-emitting chip is installed into the respective section, the pins are disposed in the connecting holes.

This application further discloses a display device, which includes a driving circuit and a light board as described above. The driving circuit drives the light board.

This application further discloses a method of assembling a light board, which is applied to the light board as described above and includes the following steps:
pouring the light-emitting chips onto the bottom plate;
using the assembling structure to drive the main capacitor plate to move in a direction toward or away from the bottom plate to adjust the position of each light-emitting chip;
wherein when the main capacitor plate is powered on, the top surface of each light-emitting chip moves toward the main capacitor plate.

In the light board of this application, by arranging the main capacitor plate and arranging the first electrostatic coating on the light-emitting chip 100, when the light-emitting chip is assembled on the light board, the light-emitting chips can be directly laid in the sections within the light board without adjusting the orientation in which the light-emitting chips are placed. Subsequently, the orientation in which each of the light-emitting chips 100 is placed is adjusted through the main capacitor plate and the first electrostatic coating on the light-emitting chip, thereby reducing the accuracy required when transferring large quantities of the light-emitting chips to the light board, so that the light-emitting chips can be laid on the light board and then accurately positioned and adjusted, thereby reducing the requirements for the Micro-LED mass transfer process.

### BRIEF DESCRIPTION OF DRAWINGS

The accompanying drawings are used to provide a further understanding of the embodiments according to this application, and constitute a part of the specification. They are used to illustrate the embodiments according to this application, and explain the principle of this application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a light board according to a first embodiment of this application.

FIG. 2 is a schematic cross-sectional diagram of a light board according to the first embodiment of this application.

FIG. 3 is a schematic diagram of a light-emitting chip in the first embodiment of this application.

FIG. 4 is a schematic cross-sectional view of the light-emitting chip in the first embodiment of this application.

FIG. 5 is an exploded cross-sectional view of the light-emitting chip in the first embodiment of this application.

FIG. 6 is a schematic diagram of a light board according to a second embodiment of this application.

FIG. 7 is an enlarged view of portion A shown in FIG. 6 of this application.

FIG. 8 is a schematic diagram of a light board according to a fourth embodiment of this application.

FIG. 9 is an enlarged view of portion B shown in FIG. 8 of this application.

FIG. 10 is a schematic diagram of a light board according to a fifth embodiment of this application.

FIG. 11 is a schematic diagram of a light board according to a sixth embodiment of this application.

FIG. 12 is a schematic diagram of a light-emitting chip in the sixth embodiment of this application.

FIG. 13 is a schematic diagram of a display device according to a seventh embodiment of this application.

FIG. 14 is a flowchart of a method of installing a light board according to an eighth embodiment of this application.

In the drawings: 100. Light-emitting chip; 110. First chip; 111. First groove; 112. Second magnetic attraction layer; 113. First connecting piece; 120. Second chip; 121. First side; 122. Second side; 123. First protrusion; 124. Second protrusion; 125. First magnetic attraction layer; 126. Third magnetic attraction layer; 130. Third chip; 131. Second groove; 132. Fourth magnetic attraction layer; 133. Second connecting piece; 140. First electrostatic coating; 141. Second electrostatic coating; 142. Third electrostatic coating; 143. Fourth electrostatic coating; 144. Fifth electrostatic coating; 200. Light board; 300. Bottom plate; 301. Accommodating groove; 302. Receiving groove; 310. Partition plate; 311. Sub-capacitor plate; 320. Sunken groove; 321. Elastic piece; 322. Support plate; 400. Main capacitor plate; 500. Assembling structure; 510. Driving piece; 520. Transmission assembly; 521. First transmission gear; 522. Second transmission gear; 523. Crank rod; 524. Second gear; 525. Third gear; 526. Rotating rod; 527. Support rod; 527A. Main rod; 527B. Sliding rod; 528. Connecting belt; 529. Torsion spring; 530. Connecting rod; 531. Suction piece; 600. Power supply board; 610. Connecting hole; 700. Driving circuit; 800. Display device.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Term “comprising”, “including”, and any variants thereof mean non-exclusive inclusion, so that one or more other features, integers, steps, operations, units, components, and/or combinations thereof may be present or added.

In addition, terms “center”, “transverse”, “up”, “down”, “left”, “right”, “vertical”, “horizontal”, “top”, “bottom”, “inside”, “outside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

Furthermore, as used herein, terms “installed on”, “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in this application can be understood depending on specific contexts.

This application will be described in detail below with reference to the accompanying drawings and optional embodiments. It should be noted that, should no conflict is present, the various embodiments or technical features described below can be combined arbitrarily to form new embodiments.

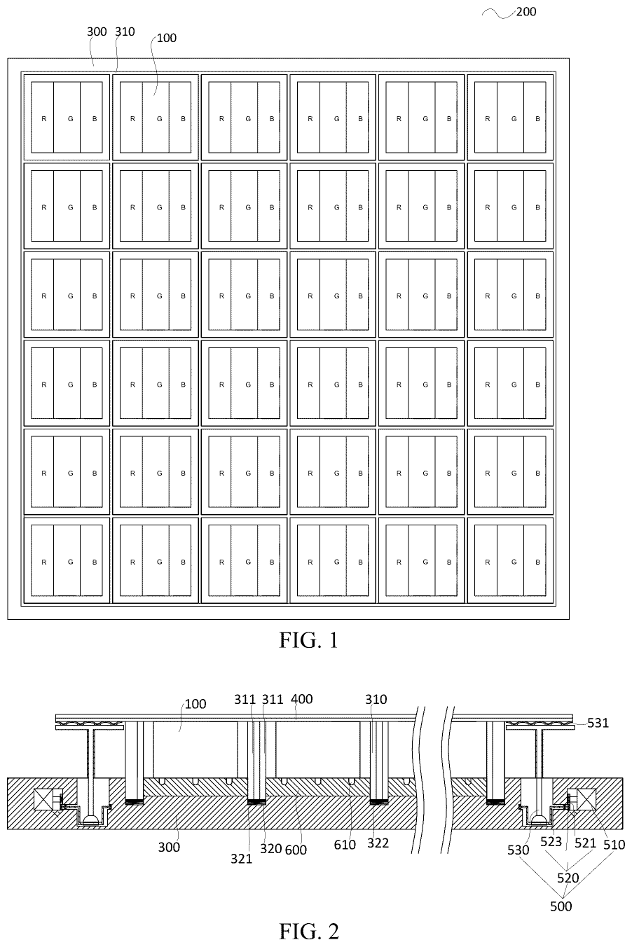

As illustrated in FIGS. 1 and 2, as a first embodiment of this application, a light board 200 is disclosed. The light board 200 is applied to a display device 800. The light board 200 includes a bottom plate 300, a plurality of light-emitting chips 100, a main capacitor plate 400, and an assembling structure 500. A plurality of partition plates 310 are disposed on the bottom plate 300. The plurality of partition plates 310 divide the bottom plate 300 into a plurality of sections. The plurality of light-emitting chips 100 are respectively arranged in the plurality of sections. A first electrostatic coating 140 is disposed on a top surface of each light-emitting chip 100. The main capacitor plate 400 is arranged opposite to the bottom plate 300. The light-emitting chips 100 are disposed between the bottom plate 300 and the main capacitor plate 400. The assembling structure 500 is arranged on the bottom plate 300. The assembling structure 500 is connected to the main capacitor plate 400. The assembling structure 500 drives the main capacitor plate 400 to move toward or away from the bottom plate 300 in a reciprocating manner. When the main capacitor plate 400 is powered on, each light-emitting chip 100 moves toward the main capacitor plate 400 under the action of the first electrostatic coating 140. The assembling structure 500 drives the main capacitor plate 400 to move in a direction away from the bottom plate 300 to drive the light-emitting chips 100 into motion so that each light-emitting chip 100 rotates until the top surface of the light-emitting chip 100 is attached with the main capacitor plate 400. The light emitted by the light-emitting chip 100 may pass through the main capacitor plate 400 and emit out of the main capacitor plate 400 for display. In this embodiment, the main capacitor plate 400 may be made of a light-transmitting material, so that the light emitted by the light-emitting chip 100 can pass through the main capacitor plate 400.

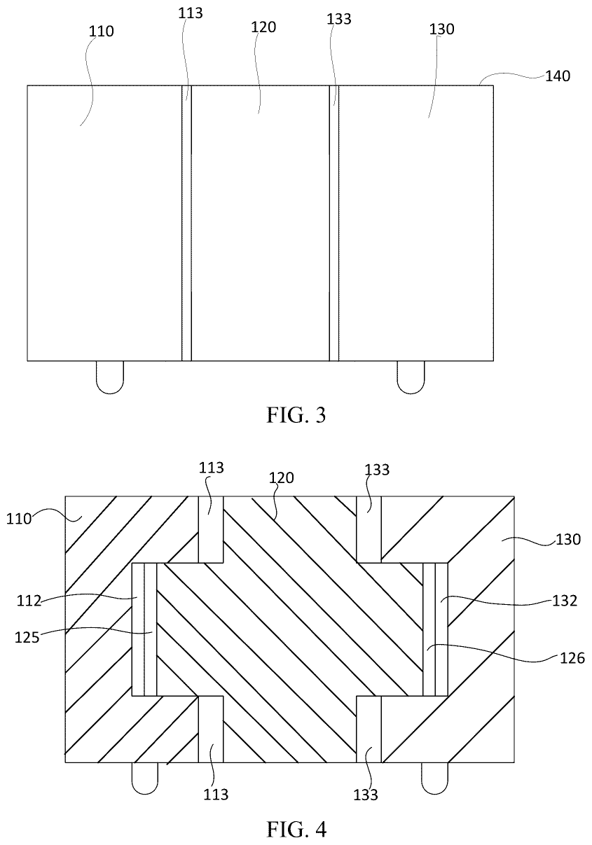

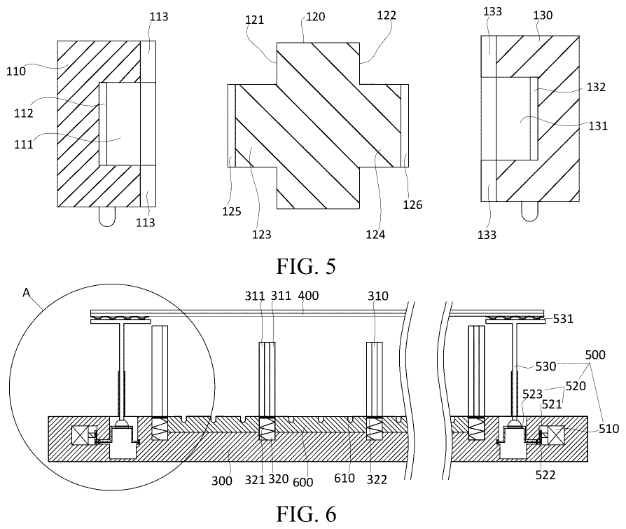

As illustrated in FIGS. 3 to 5, the light-emitting chip 100 includes a first chip 110, a second chip 120, and a third chip 130. The second chip 120 includes a first side 121 and a second side 122. The first side 121 includes a first protrusion 123. The second side 122 includes a second protrusion 124. The first chip 110 includes a first groove 111. The third chip 130 includes a second groove 131. The first chip 110 is disposed on the first side 121, and the first groove 111 is mated with the first protrusion 123. The third chip 130 is disposed on the second side 122, and the second groove 131 is mated with the second protrusion 124. The first chip 110 and the third chip 130 are symmetrically arranged about a central axis of the second chip 120. The first groove 111 only mates with the first protrusion 123. The second groove 131 only mates with the second protrusion 124. The first chip 110, the second chip 120, and the third chip 130 are combined to form the light-emitting chip 100, so as to be applied to the light board 200 in this embodiment. In this embodiment, the first chip 110 is a red chip, the second chip 120 is a green chip, and the third chip 130 is a blue chip. The first chip 110, the second chip 120, and the third chip 130 together form the light-emitting chip 100. Of course, the first chip 110 is not limited to the red chip, the second chip 120 is not limited to the green chip, and the third chip 130 is not limited to the blue chip. Designers can choose the design depending on the actual situation, and there are no restrictions thereto.

In order to more conveniently assemble the first chip 110 and the third chip 130 to the first side 121 and the second side 122 of the second chip 120, a first magnetic attraction layer 125 is disposed on the first protrusion 123, a second magnetic attraction layer 112 is disposed in the first groove 111, a third magnetic attraction layer 126 is disposed on the second protrusion 124, and a fourth magnetic attraction layer 132 is disposed in the second groove 131. The first magnetic attraction layer 125 and the second magnetic attraction layer 112 are operative to be attracted to each other. The third magnetic attraction layer 126 and the fourth magnetic attraction layer 132 are operative to be attracted to each other. The first magnetic attraction layer 125 and the third magnetic attraction layer 126 have opposite polarities. The second magnetic attraction layer 112 and the fourth magnetic attraction layer 132 have opposite polarities. When assembling the light-emitting chip 100, since the first groove 111 is fitted with the first protrusion 123 and the second groove 131 is fitted with the second protrusion 124, the second magnetic attraction layer 112 in the first groove 111 of the first chip 110 and the first magnetic attraction layer 125 of the first protrusion 123 of the second chip 120 attract each other to approach each other, so that the first groove 111 of the first chip 110 and the first protrusion 123 of the second chip 120 can be more easily mated together. The fourth magnetic attraction layer 132 in the second groove 131 of the third chip 130 and the third magnetic attraction layer 126 of the second protrusion 124 of the second chip 120 attract each other to approach each other, so that the second groove 131 of the third chip 130 and the second protrusion 124 of the second chip 120 can be more easily mated together. Under the action of the first magnetic attraction layer 125, the second magnetic attraction layer 112, the third magnetic attraction layer 126, and the fourth magnetic attraction layer 132, the first chip 110, the third chip 130, and the second chip 120 can be more easily assembled to form the light-emitting chip 100. It should be noted that although the second magnetic attraction layer 112 of the first chip 110 may be attracted with the fourth magnetic attraction layer 132 of the third chip 130, since the second magnetic attraction layer 112 of the first chip 110 is located in the first groove 111 and the fourth magnetic attraction layer 132 of the third chip 130 is located in the second groove 131, even if the first chip 110 and the third chip 130 are attracted to each other, the first chip 110 and the third chip 130 can be separated by a slight force.

When assembling the light board 200 of this embodiment, the bottom plate 300 is first fixed. The bottom plate 300 has been divided into multiple sections through multiple partition plates 310, and one light-emitting chip 100 is laid in each section. At this point, there is no need to first adjust the orientation in which the light-emitting chip 100 is placed, and it is merely needed to ensure that the light-emitting chip 100 is laid in each section. The main capacitor plate 400 is then installed on the assembling structure 500 so that the main capacitor plate 400 is connected to the assembling structure 500. When the main capacitor plate 400 is energized, each light-emitting chip 100 may gradually move from the respective section toward the main capacitor plate 400 under the action of the respective first electrostatic coating 140. If the top surface of the light-emitting chip 100 is the side facing the main capacitor plate 400, then the top surface of the light-emitting chip 100 may be directly attached to the main capacitor plate 400 under the action of the first electrostatic coating 140. Otherwise if the top surface of the light-emitting chip 100 is the side facing away from the main capacitor plate 400, the light-emitting chip 100 may move toward the main capacitor plate 400. However, since the light-emitting chip 100 is located in the respective section, the light-emitting chip 100 cannot be flipped over so as to be attached to the main capacitor plate 400. At this point, the assembling structure 500 is needed to be used. The assembling structure 500 drives the main capacitor plate 400 to move in a direction away from the bottom plate 300, thereby driving the light-emitting chip 100 to leave the section. At this point, the light-emitting chip 100 has enough flipping space. The light-emitting chip 100 can rotate to make the top surface of the light-emitting chip 100 fit with the main capacitor plate 400. At this point, all the light-emitting chips 100 on the light board 200 are adjusted so that the top surface of each of the light-emitting chips 100 faces the main capacitor plate 400. Then the assembling structure 500 is used to drive the main capacitor plate 400 to move in a direction towards the bottom plate 300 to install the light-emitting chips 100 into the sections thus realizing the installation of the light-emitting chips 100. In a word, in the light board 200 of this embodiment, by providing the main capacitor plate 400 and arranging the first electrostatic coating 140 on the light-emitting chip 100, when assembling the light-emitting chips 100 to the light board 200, the light-emitting chips 100 can be directly laid in the sections within the light board 200 without adjusting the orientation in which the light-emitting chips 100 are placed. Subsequently, the orientation in which each light-emitting chip 100 is placed is adjusted through the main capacitor plate 400 and the first electrostatic coating 140 on the light-emitting chip 100, so as to realize the installation of the light-emitting chips 100, thereby reducing the accuracy required when large quantities of the light-emitting chips 100 are transferred to the light board 200, so that the light-emitting chips 100 can be laid on the light board 200 and then accurately adjusted in position, thereby reducing the requirements on the Micro-LED mass transfer process. Furthermore, when comparing this embodiment in which the light-emitting chip 100 is used to be installed on the Micro-LED display screen against with the RGB solution that requires three chips of red, green and blue that are evenly spaced in the horizontal plane to form an RGB effect, the light-emitting chip 100 of this embodiment poses relatively low requirements for the mass transfer process when installed on the Micro-LED display. Since the first chip 110, the third chip 130, and the second chip 120 are first assembled as the light-emitting chip 100 and then installed on the light board 200, the number of chips that need to be transferred and installed in large quantities on the light board 200 is greatly reduced, so that the requirements for the mass transfer process are reduced, thereby improving the production yield of Micro-LED displays, and also reducing the difficulty of assembly, making it easier to produce Micro-LED displays. The design of the light board 200 and the design of the light-emitting chip 100 in this embodiment are complementary to each other.

Further, the assembling structure 500 includes a driving piece 510, a transmission assembly 520, and a connecting rod 530. The driving piece 510 is connected to the transmission assembly 520. The transmission assembly 520 is connected to the connecting rod 530. The connecting rod 530 is connected to the main capacitor plate 400. When the driving piece 510 is operating, the driving piece 510 drives the transmission assembly 520 to move. The transmission assembly 520 drives the connecting rod 530 to move back and forth in a direction approaching or away from the bottom plate 300, thereby driving the main capacitor plate 400 to move. A suction piece 531 is disposed on the connecting rod 530. The suction piece 531 is connected to the main capacitor plate 400 to hold the main capacitor plate 400 onto the connecting rod 530. In this embodiment, the suction piece 531 may be a small suction ball, and the driving piece 510 may be a motor. The motor is connected to the connecting rod 530 through the transmission assembly 520 to drive the main capacitor plate 400 to move. The main capacitor plate 400 is held on the connecting rod 530 through the small suction ball. The small suction ball may be provided in multiple. The multiple small suction balls may be held onto the main capacitor plate 400 at the same time to ensure the stability of the connection between the connecting rod 530 and the main capacitor plate 400. The assembling structure 500 may be disposed at multiple locations, and the multiple assembling structures 500 may be respectively disposed on four sides of the bottom plate 300 to achieve stable support for the main capacitor plate 400.

A power supply board 600 is further disposed on the bottom plate 300. The power supply plate 600 includes connecting holes 610. Pins are disposed on a bottom surface of the light-emitting chip 100. When each light-emitting chip 100 is installed in the respective section, the pins are located in the connecting holes 610, and the power supply board 600 is electrically connected to the light-emitting chip 100 through the connecting holes 610 and pins to provide power for the light-emitting chip 100 for use, thereby performing display of images. The first chip 110 includes a first connecting piece 113. The third chip 130 includes a second connecting piece 133. When the first chip 110 and the third chip 130 are combined with the second chip 120 to form the light-emitting chip 100, the first chip 110 and the second chip 120 are electrically connected through the first connecting piece 113, and the third chip 130 and the second chip 120 are connected through the second connecting piece 133. The first connecting piece 113 and the second connecting piece 133 may be conductor layers or connecting circuit layers. In this way, in the assembled light-emitting chip 100, it is only needed to set pins solely on any one of the first chip 110, the third chip 130, or the second chip 120, so that the first chip 110, the third chip 130 and the second chip 120 of the light-emitting chip 100 can be powered together through these pins, thereby achieving the design of saving pins. In this embodiment, if the first connecting piece 113 and the second connecting piece 133 are conductor layers, then the conductor layers may be made of metallic copper, so that the conductor layers have good electrical conductivity. Of course, the designer may still set pins on the first chip 110, the third chip 130 and the second chip 120 in sequence for connection and power supply. At the same time, the first chip 110 and the second chip 120 may also be powered together through the first connecting piece 113, and the third chip 130 and the second chip 120 may also be powered together through the second connecting piece 133, thereby improving the fault tolerance rate for abnormal pins on the first chip 110, the third chip 130, and the second chip 120 when assembling the light-emitting chip 100 onto the light board 200. Each light-emitting chip 100 only needs to ensure that the pins of any one of the first chip 110, the third chip 130, or the second chip 120 are normal before they can be used and powered, which greatly improves the fault tolerance rate of installation. It should be noted that the first connecting piece 113 only needs to electrically connect the first chip 110 and the second chip 120, and the second connecting piece 133 only needs to electrically connect the third chip 130 and the second chip 120. Designers can choose and design the specific connection structures according to actual needs, and there are no restrictions thereto.

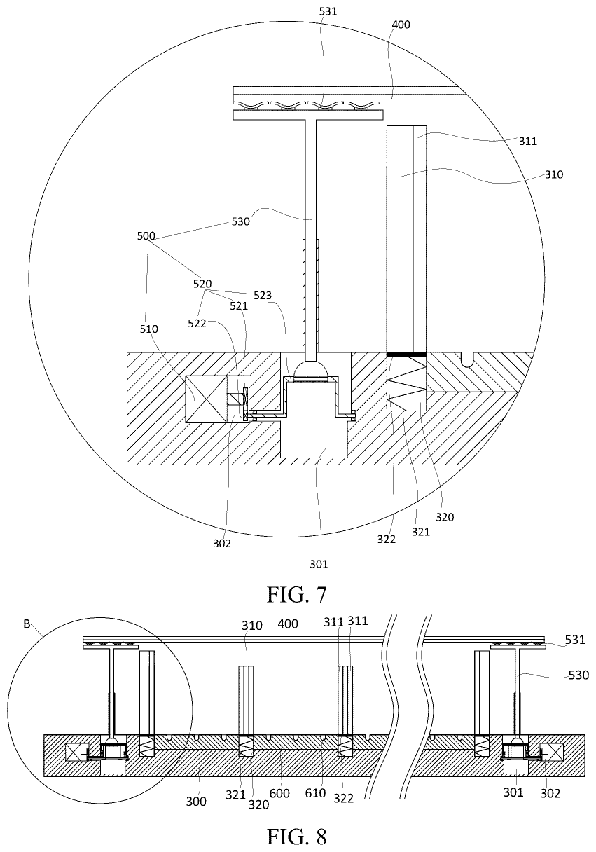

As illustrated in FIGS. 6 and 7, as a second embodiment of this application, which is a further refinement of the first embodiment of this application, a light board 200 is disclosed. The transmission assembly 520 includes a first transmission gear 521, a second transmission gear 522, and a crank rod 523. The driving piece 510 includes a motor. The output shaft of the motor is connected to the first transmission gear 521. The first transmission gear 521 meshes with the second transmission gear 522. The second transmission gear 522 is connected to the crank rod 523. The crank rod 523 is connected to the connecting rod 530. In this way, when the assembling structure 500 of this embodiment is in use, the motor may be started to work. The output shaft of the motor is connected to the first transmission gear 521. The first transmission gear 521 meshes with the second transmission gear 522. The second transmission gear 522 is connected to the crank rod 523. Thus, the motor can directly drive the crank rod 523 through the first transmission gear 521 and the second transmission gear 522 so that the crank rod 523 makes a circular motion. The connecting rod 530 disposed on the crank rod 523 may move as the crank rod 523 moves, thereby driving the main capacitor plate 400 to reciprocate in a direction approaching or away from the bottom plate 300. In this embodiment, the first transmission gear 521, the second transmission gear 522, and the crank rod 523 are arranged to drive the connecting rod 530 to move, where the operation is realized through multi-stage motion transmission. The bottom plate 300 includes a accommodating groove 301 and a receiving groove 302. The accommodating groove 301 and the receiving groove 302 are connected to each other. The motor is arranged in the receiving groove 302. The first transmission gear 521 and the second transmission gear 522 are also arranged in the receiving groove 302. The crank rod 523 is arranged in the accommodating groove 301. One end of the crank rod 523 extends into the receiving groove 302 and is connected to the second transmission gear 522. The crank rod 523 is rotatably arranged in the accommodating groove 301. With this arrangement, most of the assembling structure 500 is disposed inside the bottom plate 300, thereby saving the external space of the bottom plate 300 and making the appearance of the light board 200 more neat and exquisite.

As a third embodiment of this application, which is a further refinement of the first embodiment of this application, a light board 200 is disclosed. The transmission assembly 520 includes a first gear and a connecting rack. The first gear is connected to the output shaft of the motor. One end of the connecting rack includes teeth that mesh with the first gear, and the other end is fixedly connected to the connecting rod 530. The connecting rack meshes with the first gear, so that when the first gear is driven to rotate by the motor, the connecting rack can reciprocate in a direction approaching or away from the bottom plate 300, thereby driving the connecting rod 530 and the main capacitor plate 400 to move, thereby adjusting the top surface of the light-emitting chip 100 to face the main capacitor to realize the installation of the light-emitting chip 100.

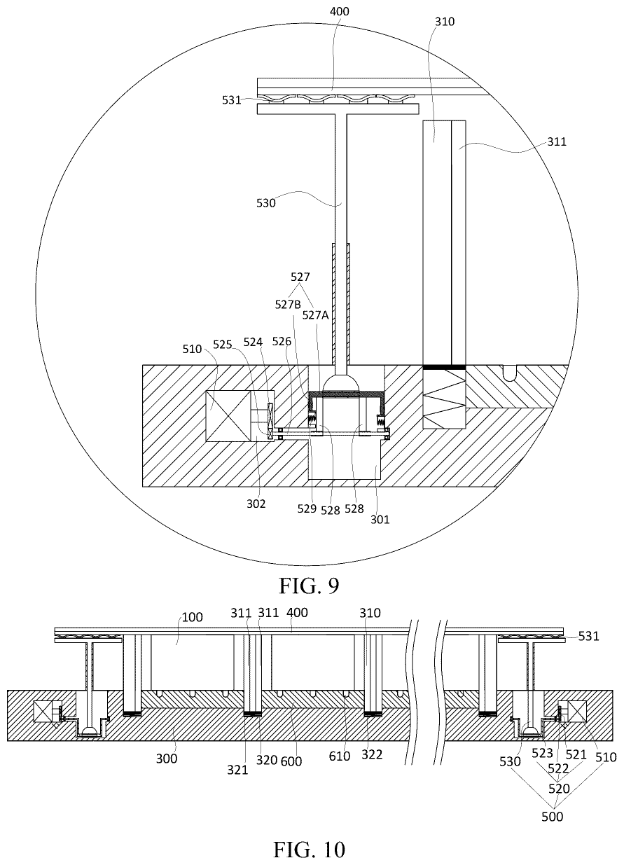

As illustrated in FIGS. 8 and 9, as a fourth embodiment of this application, which is a further refinement of the first embodiment of this application, a light board 200 is disclosed. The driving piece 510 includes a motor. The transmission assembly 520 includes a second gear 524, a third gear 525, a rotating rod 526, a support rod 527, and a connecting belt 528. The bottom plate 300 includes a accommodating groove 301 and a receiving groove 302. The accommodating groove 301 and the receiving groove 302 are connected to each other. The motor is arranged in the receiving groove 302. The second gear 524 and the third gear 525 are also disposed in the receiving groove 302. The output shaft of the motor is connected to the second gear 524. The second gear 524 meshes with the third gear 525. The rotating rod 526 and the support rod 527 are arranged in the accommodating groove 301. One end of the rotating rod 526 extends into the receiving groove 302 and is connected to the third gear 525. A fixing shaft and a fixing sleeve are disposed on a groove wall of the accommodating groove 301. Two fixing sleeves and two fixing shafts are provided. The support rod 527 includes a main rod 527A and sliding rods 527B arranged on both sides of the main rod 527A. The main rod 527A is connected to the connecting rod 530. The sliding rod 527B is sleeved on the fixing sleeve and can slide back and forth along the orientation of the fixing sleeve. The fixing shaft is sleeved with a torsion spring 529. One end of the torsion spring 529 is fixed, and the other end abuts against the sliding rod 527B. When the support rod 527 moves in the direction of the torsion spring 529, the sliding rods 527B may compress the torsion spring 529 to cause elastic deformation. One end of the connecting belt 528 is fixed to the rotating rod 526, and the other end is fixed to the support rod 527. In use, when the motor is operating, the motor will drive the second gear 524 and the third gear 525 to rotate to drive the rotating rod 526 to rotate, so that the connecting belt 528 on the rotating rod 526 is rolled up. At this point, the support rod 527 connected to the other end of the connecting belt 528 will gradually move toward the direction of the torsion spring 529 as the connecting belt 528 is rolled up. The sliding rods 527B of the support rod 527 may thus compress the torsion spring 529 to cause elastic deformation. At this point, the support rod 527 moves toward the bottom plate 300 to drive the connecting rod 530 to move toward the bottom plate 300. When the connecting rod 530 needs to move in a direction away from the bottom plate 300, the motor only needs to stop operating to stop the rotation of the rotating rod 526. Under the elastic force of the torsion spring 529, the support rod 527 may move in a direction away from the bottom plate 300 to drive the connecting rod 530 to move. The above structure may be used to realize the reciprocating movement of the connecting rod 530 and the main capacitor plate 400 in the direction approaching or away from the bottom plate 300, thereby adjusting the top surface of the light-emitting chip 100 to face the main capacitor plate 400 to realize the installation of the light-emitting chip 100.

As illustrated in FIG. 10, as the fifth embodiment of this application, which is an improvement of the first embodiment of this application, a light board 200 is disclosed. The bottom plate 300 further includes a sunken groove 320. The sunken groove 320 is arranged corresponding to the partition plate 310. The elastic piece 321 is disposed in the sunken groove 320. A support plate 322 is disposed on one end of the partition plate 310 adjacent to the sunken groove 320. One end of the elastic piece 321 abuts on the bottom of the sunken groove 320, and the other end abuts on the support plate 322. When the main capacitor plate 400 moves toward the bottom plate 300, the main capacitor plate 400 contacts the partition plate 310 to drive the partition plate 310 to move toward the bottom of the sunken groove 320. After the orientation adjustment of the light-emitting chip 100 is completed, the assembling structure 500 drives the main capacitor plate 400 to move toward the bottom plate 300. The main capacitor plate 400 abuts against the partition plate 310 to drive the partition plate 310 to move toward the bottom of the sunken groove 320, thereby pressing the light-emitting chip 100 in the section to avoid problems such as movement of the light-emitting chip 100 due to the orientation in which the light board 200 is placed during use. At the same time, the light-emitting chip 100 may also be tightly pressed on the bottom plate 300 to prevent the pins of the light-emitting chip 100 from being separated from the connecting holes 610 of the power supply board 600 thereby causing the light-emitting chip 100 to be powered off.

The height of the partition plate 310 disposed at the outermost side of the light board 200 is greater than the height of the partition plate 310 disposed at other positions of the light board 200. The depth of the groove disposed corresponding to the outermost partition plate 310 is greater than the depth of the groove disposed corresponding to the partition plates 310 at other positions. That is, the height of the partition plate 310 disposed at the edges of the bottom plate 300 is greater than the height of the partition plate 310 disposed at other positions of the bottom plate 300. In this way, when assembling the light-emitting chips 100, the light-emitting chips 100 may be poured directly onto the bottom plate 300, so that there is at least one light-emitting chip 100 in each section to the greatest extent. Then a thin film may be used to abut against the two outermost partition plates 310 and then the thin film is straightened to suck up the excess light-emitting chips 100 to ensure that there is only one light-emitting chip 100 in each section, and then the orientation of the light-emitting chip 100 is adjusted.

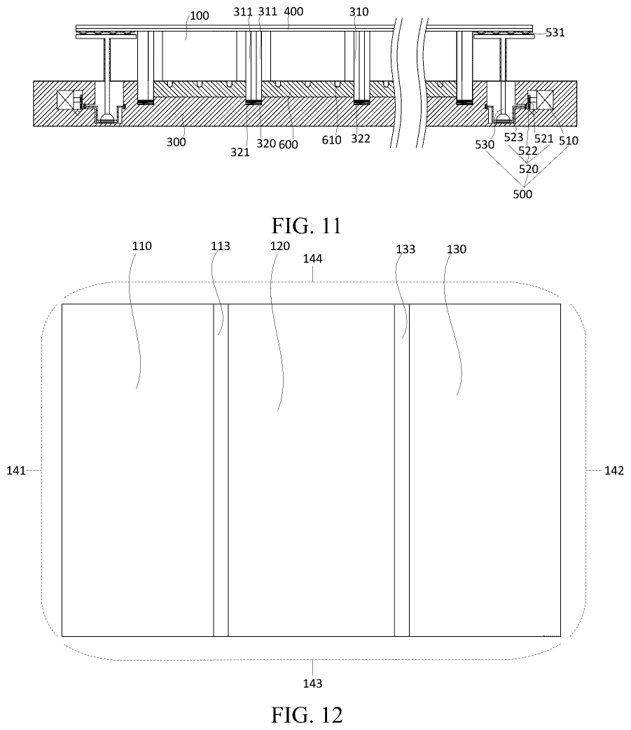

As illustrated in FIG. 11, as a sixth embodiment of this application, a light board 200 is disclosed. A sub-capacitor plate 311 is also disposed on the partition plate 310. The sub-capacitor plate 311 is disposed on the side of the partition plate 310 facing the respective section. The polarities of the opposite sub-capacitor plates 311 in each of the sections are opposite. The adjacent sub-capacitor plates 311 have the same polarity. Take one section as an example. The section includes four directions: front, back, left, and right. The sub-capacitor plate 311 located in the front position and the sub-capacitor plate 311 located in the rear position have opposite polarities. The sub-capacitor plate 311 located on the left and the sub-capacitor plate 311 located on the right have opposite polarities. The sub-capacitor plate 311 located in the front position may have the same polarity as the sub-capacitor plate 311 located in the left position. The sub-capacitor plate 311 located at the rear position may have the same polarity as the sub-capacitor plate 311 located at the right position. As illustrated in FIG. 12, in this embodiment, a second electrostatic coating 141 is disposed on the side of the light-emitting chip 100 on which the first chip 110 is disposed. A third electrostatic coating 142 is disposed on the side of the light-emitting chip 100 where the third chip 130 is disposed. A fourth electrostatic coating 143 is disposed on the front side of the light-emitting chip 100. A fifth electrostatic coating 144 is disposed on the back of the light-emitting chip 100. The second electrostatic coating 141 and the third electrostatic coating 142 may have opposite charge polarities. The fourth electrostatic coating 143 and the fifth electrostatic coating 144 may have opposite charge polarities. In this embodiment, the first electrostatic coating 140, the second electrostatic coating 141, the third electrostatic coating 142, the fourth electrostatic coating 143, and the fifth electrostatic coating 144 are disposed on the light-emitting chip 100. Furthermore, the charge polarities of the second electrostatic coating 141 and the third electrostatic coating 142 are opposite, and the charge polarities of the fourth electrostatic coating 143 and the fifth electrostatic coating 144 are opposite, so that after the light-emitting chip 100 is assembled on the light board 200, orientational positioning can be performed through the arranged first electrostatic coating 140, second electrostatic coating 141, third electrostatic coating 142, fourth electrostatic coating 143, and fifth electrostatic coating 144 thus realizing the assembly of the light-emitting chip 100 and ensuring that the arrangement of each light-emitting chip 100 is identical.

During assembly, the light-emitting chips 100 may be laid directly into the section, and there is no need to first adjust the orientation in which each of the light-emitting chips 100 is placed; it is only needed to ensure that there is a light-emitting chip 100 laid in each section. The main capacitor plate 400 is then installed on the assembling structure 500 so that the main capacitor plate 400 is connected to the assembling structure 500. The main capacitor plate 400 is energized. Under the action of the first electrostatic coating 140, the light-emitting chips 100 will gradually move from the sections toward the main capacitor plate 400. Then the assembling structure 500 is used to drive the main capacitor plate 400 to move in a direction away from the bottom plate 300, thereby driving the light-emitting chip 100 to leave the respective section. At this point, the light-emitting chip 100 has enough turning space, and the light-emitting chip 100 can rotate to make the top surface of the light-emitting chip 100 fit with the main capacitor plate 400. At this point, all the light-emitting chips 100 on the light board 200 are adjusted so that the top surfaces of the light-emitting chips 100 are attached with the main capacitor plate 400. The assembling structure 500 is then used to drive the main capacitor plate 400 to move toward the bottom plate 300 to install the light-emitting chips 100 into the sections. Then, the sub-capacitor plates 311 arranged in various directions in the section are energized. Under the action of the second electrostatic coating 141, the third electrostatic coating 142, the fourth electrostatic coating 143, and the fifth electrostatic coating 144 disposed on the sub-capacitor plate 311 and the light-emitting chip 100, the light-emitting chip 100 is forced to move, and will eventually reach the force balance position, that is, the center position of the section, thereby achieving complete orientational positioning, so that the orientations of all light-emitting chip 100 on the light board 200 are consistent, thereby realizing the mass transfer and installation of the light-emitting chips 100 on the light board 200. In the light board 200 in this embodiment, the first electrostatic coating 140, the second electrostatic coating 141, the third electrostatic coating 142, the fourth electrostatic coating 143, and the fifth electrostatic coating 144 are disposed on the light-emitting chip 100, and the sub-capacitor plates 311 are disposed at various directions in the sections. Thus, the orientation of each light-emitting chip 100 is positioned by the first electrostatic coating 140, the second electrostatic coating 141, the third electrostatic coating 142, the fourth electrostatic coating 143, and the fifth electrostatic coating 144 to complete the assembly of the light-emitting chips 100 and ensure that each light-emitting chip 100 is arranged identically, thereby improving the mass transfer efficiency and accuracy of the light-emitting chips 100. Compared with the original Micro-LED mass transfer process, it reduces the requirements on the Micro-LED mass transfer process, improves the production yield of Micro-LED displays, and also reduces the difficulty of assembly, making it easier to produce Micro-LED displays. The designs of the light board 200 and the light-emitting chip 100 in this embodiment are complementary to each other.

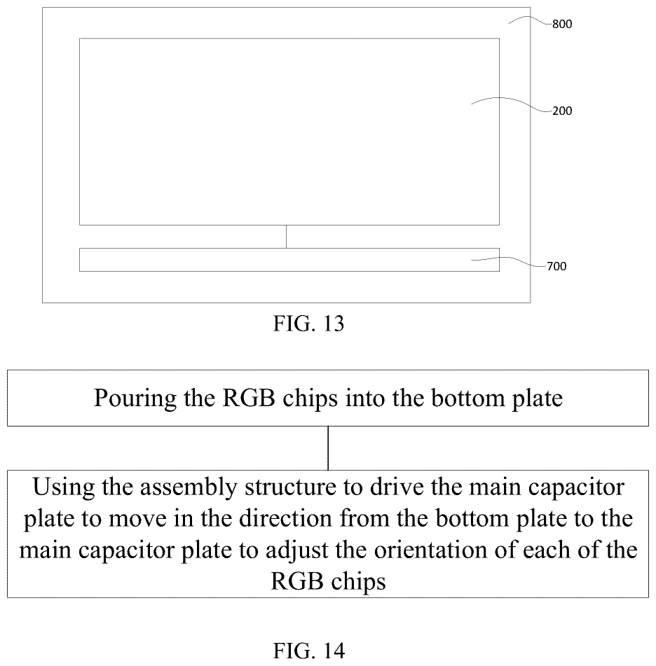

As illustrated in FIG. 13, as a seventh embodiment of this application, a display device 800 is disclosed. The display device 800 includes a driving circuit 700 and the light board 200 as described in the above embodiments. The driving circuit 700 drives the light board 200. In the display device 800 of this embodiment, by arranging the main capacitor plate 400 and arranging the first electrostatic coating 140 on the light-emitting chip 100, when the light-emitting chips 100 are assembled on the light board 200, the light-emitting chips 100 can be directly laid in the sections within the light board 200 without adjusting the orientation in which the light-emitting chips 100 are each placed. Subsequently, the orientation in which the light-emitting chips 100 are each placed is adjusted through the main capacitor plate 400 and the first electrostatic coating 140 on the light-emitting chip 100, thereby reducing the accuracy required when transferring large quantities of the light-emitting chips 100 to the light board 200, which allows the light-emitting chips 100 to be laid on the light board 200 and then accurately positioned and adjusted, thereby reducing the requirements for Micro-LED mass transfer process.

As illustrated in FIG. 14, as an eighth embodiment of this application, a method of assembling a light board is disclosed, which is applied to the light board described in the above embodiment and includes the following steps:
pouring the light-emitting chips into the bottom plate;
using the assembling structure to drive the main capacitor plate to move in a direction toward or away from the bottom plate to adjust the position of each light-emitting chip;
wherein when the main capacitor plate is powered on, the top surface of each light-emitting chip moves toward the main capacitor plate.

By arranging the main capacitor plate 400 and arranging the first electrostatic coating 140 on the light-emitting chip 100, when the light-emitting chip 100 is assembled on the light board 200, the light-emitting chips 100 can be directly laid in the sections within the light board 200 without adjusting the orientation in which the light-emitting chips 100 are each placed. Subsequently, the orientation in which the light-emitting chip 100 is placed is adjusted through the main capacitor plate 400 and the first electrostatic coating 140 on the light-emitting chip 100, thereby reducing the accuracy required when transferring large quantities of the light-emitting chips 100 to the light board 200, so that the light-emitting chips 100 can be laid on the light board 200 and then accurately positioned and adjusted, thereby reducing the requirements for the Micro-LED mass transfer process.

It should be noted that the limitations of various operations involved in this solution will not be deemed to limit the order of the operations, provided that they do not affect the implementation of the specific solution, so that the operations written earlier may be executed earlier or they may also be executed later or even at the same time. As long as the solution can be implemented, they should all be regarded as falling in the scope of protection of this application.

It should be noted that the inventive concept of this application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of this application made with reference to some specific illustrative embodiments, and the specific implementations of this application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A light board applied to a display device, the light board comprising:
a bottom plate, wherein there is disposed a plurality of partition plates on the bottom plate, and wherein the plurality of partition plates divide the bottom plate into a plurality of sections;
a plurality of light-emitting chips, respectively arranged in the plurality of sections, wherein there is disposed a first electrostatic coating on a top surface of each of the plurality of light-emitting chips;
a main capacitor plate, arranged opposite to the bottom plate, wherein the plurality of light-emitting chips are disposed between the bottom plate and the main capacitor plate; and
an assembling structure, arranged on the bottom plate, the assembling structure being connected to the main capacitor plate and being operative to drive the main capacitor plate to reciprocate in a direction toward or away from the bottom plate;
wherein in response to the main capacitor plate being energized, each of the plurality of light-emitting chips is operative to move toward the main capacitor plate under the action of the respective first electrostatic coating, and wherein the assembling structure is operative to drive the main capacitor plate to move in a direction away from the bottom plate to drive each of the plurality of light-emitting chips to rotate until the top surface of the light-emitting chip is attached to the main capacitor plate;
wherein light emitted by each of the plurality of light-emitting chips is operative to pass through the main capacitor plate and be emitted out of the main capacitor plate for display.

2. The light board as recited in claim 1, wherein the assembling structure comprises a driving piece, a transmission assembly, and a connecting rod; wherein the driving piece is connected to the transmission assembly, the transmission assembly is connected to the connecting rod, and the connecting rod is connected to the main capacitor plate;
wherein the driving piece when operating is operative to drive the transmission assembly to move, and the transmission assembly is operative to drive the connecting rod to move back and forth in a direction toward or away from the bottom plate, thereby driving the main capacitor plate to move.

3. The light board as recited in claim 2, wherein the driving piece comprises a motor; wherein the transmission assembly comprises a first transmission gear, a second transmission gear, and a crank rod; wherein an output shaft of the motor is connected to the first transmission gear, wherein the first transmission gear is engaged with the second transmission gear, wherein the second transmission gear is connected to the crank rod, and wherein he crank rod is connected to the connecting rod.

4. The light board as recited in claim 2, wherein there is disposed a suction piece on the connecting rod, wherein the suction piece is connected to the main capacitor plate to hold the main capacitor plate onto the connecting rod.

5. The light board as recited in claim 2, wherein the bottom plate comprises a groove disposed corresponding to each of the plurality of partition plates; wherein there is disposed an elastic piece inside the groove, wherein there is disposed a support plate on one end of each partition plate facing the respective groove; wherein one end of the elastic piece abuts on a bottom of the groove, and another end abuts on the respective support plate; wherein when the main capacitor plate moves toward the bottom plate, the main capacitor plate contacts each of the plurality of partition plates to drive each of the plurality of partition plates to move toward the bottom of the respective groove.

6. The light board as recited in claim 1, wherein there is further disposed a sub-capacitor plate on each of the plurality of partition plates, the sub-capacitor plate being disposed on a side of the respective partition plate facing the respective section; wherein sub-capacitor plates facing towards each other in each of the plurality of sections have opposite polarities, and wherein adjacent sub-capacitor plates facing away from each other have a same polarity.

7. The light board as recited in claim 5, wherein the partition plate disposed at an outermost side of the bottom plate has a height greater than a height of each of the partition plates disposed at other positions of the bottom plate; the groove disposed corresponding to the partition plate disposed at the outermost side of the bottom plate has a height that is greater than a depth of each of the grooves disposed corresponding to the partition plates at other positions.

8. The light board as recited in claim 1, wherein there is further disposed a power supply board on the bottom plate, the power supply board comprising a connecting hole; wherein pins are disposed on a bottom surface of each of the plurality of light-emitting chips, wherein when each of the plurality of light-emitting chips is installed in the respective section, the pins are disposed in the respective connecting holes.

9. The light board as recited in claim 1, wherein the main capacitor plate is made of a light-transmitting material.

10. The light board as recited in claim 1, wherein the assembling structure is disposed at a plurality of locations, and wherein the plurality of assembling structures are respectively disposed on four sides of the bottom plate to achieve a stable support for the main capacitor plate.

11. The light board as recited in claim 2, wherein the driving piece comprises a motor, wherein the transmission assembly comprises a first gear and a connecting rack, wherein the first gear is connected to an output shaft of the motor; wherein one end of the connecting rack comprises a plurality of teeth that are meshed with the first gear, and wherein another end of the connecting rack is fixedly connected to the connecting rod; wherein the connecting rack is meshed with the first gear so that when the first gear is driven to rotate by the motor, and wherein the connecting rack is operative to reciprocate in a direction toward or away from the bottom plate.

12. The light board as recited in claim 3, wherein the bottom plate comprises an accommodating groove and a receiving groove that are communicated with each other; wherein the motor is disposed in the receiving groove; wherein the first transmission gear and the second transmission gear are also arranged in the receiving groove; wherein the crank rod is disposed in the accommodating groove, wherein one end of the crank rod extends into the receiving groove and is connected with the second transmission gear, and wherein the crank rod is rotatably arranged in the accommodating groove.

13. The light board as recited in claim 2, wherein the driving piece comprises a motor, wherein the transmission assembly comprises a second gear, a third gear, a rotating rod, a support rod, and a connecting belt; wherein the bottom plate comprises a receiving groove and an accommodating groove that are communicated with each other; wherein the motor is disposed in the receiving groove, and the second gear and the third gear are also disposed in the receiving groove; wherein an output shaft of the motor is connected to the second gear, wherein the second gear is meshed with the third gear; wherein the rotating rod and the support rod are arranged in the receiving groove, wherein one end of the rotating rod extends into the receiving groove and is connected to the third gear; wherein there is disposed two fixing shafts and two fixing sleeves on a wall of the accommodating groove; wherein the support rod comprises a main rod A and two sliding rods B arranged on both sides of the main rod A; wherein the main rod A is connected to the connecting rod; wherein the two sliding rods B are respectively sleeved on the two fixing sleeves and are operative to slide back and forth along a length of the fixing sleeves; wherein there is sleeved a torsion spring on each of the two fixing shafts, wherein one end of the torsion spring is fixed, and wherein another end of the torsion spring abuts on the respective sliding rod B; wherein when the support rod moves in the direction of the torsion springs, the sliding rods B are operative to compress the torsion springs to cause an elastic deformation of the torsion springs; wherein one end of the connecting belt is fixedly connected to the rotating rod, and wherein another end of the connecting belt is fixedly connected to the support rod.

14. The light board as recited in claim 4, wherein the suction piece comprises a suction ball, and wherein there is disposed a plurality of the suction balls that are all stuck to on the main capacitor plate.

15. A display device, comprising a light board and a driving circuit configured to drive the light board; wherein the light board comprises:
a bottom plate, wherein there is disclosed a plurality of partition plates on a bottom plate, and wherein the plurality of partition plates divide the bottom plate into a plurality of sections;
a plurality of light-emitting chips, respectively arranged in the plurality of sections, wherein there is disposed a first electrostatic coating on a top surface of each of the plurality of light-emitting chips;
a main capacitor plate, arranged opposite to the bottom plate, wherein the plurality of light-emitting chips are disposed between the bottom plate and the main capacitor plate;
an assembling structure, arranged on the bottom plate, the assembling structure being connected to the main capacitor plate and being operative to drive the main capacitor plate to reciprocate in a direction toward or away from the bottom plate, wherein in response to the main capacitor plate being energized, each of the plurality of light-emitting chips is operative to move toward the main capacitor plate under the action of the respective first electrostatic coating, and wherein the assembling structure is operative to drive the main capacitor plate to move in a direction away from the bottom plate to drive each of the plurality of light-emitting chips to rotate until a top surface of the light-emitting chip is attached to the main capacitor plate;
wherein light emitted by each of the plurality of light-emitting chips is operative to pass through the main capacitor plate and be emitted out of the main capacitor plate for display.

16. The display device as recited in claim 1, wherein the assembling structure comprises a driving piece, a transmission assembly, and a connecting rod; wherein the driving piece is connected to the transmission assembly, the transmission assembly is connected to the connecting rod, and the connecting rod is connected to the main capacitor plate; wherein the driving piece when operating is operative to drive the transmission assembly to move, and wherein the transmission assembly is operative to drive the connecting rod to move back and forth in a direction toward or away from the bottom plate thereby driving the main capacitor plate to move.

17. The display device as recited in claim 16, wherein the driving piece comprises a motor, wherein the transmission assembly comprises a first transmission gear, a second transmission gear, and a crank rod; wherein an output shaft of the motor is connected to the first transmission gear, wherein the first transmission gear is meshed with the second transmission gear, wherein the second transmission gear is connected to the crank rod, and wherein the crank rod is connected to the connecting rod.

18. The display device as recited in claim 16, wherein there is disposed a suction piece on the connecting rod, wherein the suction piece is connected to the main capacitor plate to hold the main capacitor plate on the connecting rod.

19. A method of assembling a light board, the light board comprising a bottom plate, a main capacitor plate, an assembling structure, and a plurality of light-emitting chips, wherein there is disposed a plurality of partition plates on the bottom plate, and wherein the plurality of plurality of partition plates divide the bottom plate into a plurality of sections; wherein the plurality of light-emitting chips are respectively arranged in the plurality of sections; wherein there is disposed a first electrostatic coating on a top surface of each of the plurality of light-emitting chips; wherein the main capacitor plate is arranged opposite to the bottom plate, and the plurality of light-emitting chips are disposed between the bottom plate and the main capacitor plate; wherein the assembling structure is disposed on the bottom plate and is connected to the main capacitor plate, the assembling structure being operative to drive the main capacitor plate to reciprocate in a direction toward or away from the bottom plate; wherein when the main capacitor plate is energized, each of the plurality of light-emitting chips is operative to move toward the main capacitor plate under the action of the respective first electrostatic coating, and wherein the assembling structure is operative to drive the main capacitor plate to move in a direction away from the bottom plate to drive the plurality of light-emitting chips to rotate until a top surface of each of the plurality of light-emitting chips is attached with the main capacitor plate; wherein light emitted by the plurality of light-emitting chips is operative to pass through the main capacitor plate and be emitted out of the main capacitor plate for display; wherein the method comprises the following operations:
pouring the plurality of light-emitting chips onto the bottom plate;
using the assembling structure to drive the main capacitor plate to move in a direction towards or away from the bottom plate to adjust an orientation of each of the plurality of light-emitting chips;
wherein in response to the main capacitor plate being powered on, a top surface of each of the plurality of light-emitting chips is operative to toward the main capacitor plate.

20. The method as recited in claim 19, wherein the assembling structure comprises a driving piece, a transmission assembly, and a connecting rod; wherein the driving piece is connected to the transmission assembly, wherein the transmission assembly is connected to the connecting rod, and wherein the connecting rod is connected to the main capacitor plate; wherein the driving piece when operating is operative to drive the transmission assembly to move, and wherein the transmission assembly is operative to drive the connecting rod to move back and forth in a direction towards to or away from the bottom plate thereby driving the main capacitor plate to move.
